(19) United States
(12) Patent Application Publication
(10) Pub. No.: US 2008/0054348 A1
(43) Pub. Date: Mar. 6, 2008

(54) Semiconductor device and a method of fabricating the same

(75) Inventor: Kwang Young Ko, Bucheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/894,914

(22) Filed: Aug. 21, 2007

(30) Foreign Application Priority Data
Aug. 30, 2006 (KR) 10-2006-0082993

(51) Int. Cl. H01L 29/78; H01L 21/336

(52) U.S. Cl. 257/328; 438/268; 257/E29.262; 257/E21.41

(57) ABSTRACT

A semiconductor device may include a semiconductor substrate with a well area; a conductive body in the well area; a source in the body; a drift region and a drain in a vertical region of the well area other than the body; and a gate electrode between the source and the drain.

The present application claims priority under 35 U.S.C. 119 and 35 U.S.C. 365 to Korean Patent Application No. 10-2006-0082993 (filed on Aug. 30, 2006), which is hereby incorporated by reference in its entirety.

### BACKGROUND

The present invention relates to a semiconductor device and a method of fabricating the same.

A MOS field effect transistor (hereinafter, referred to as ‘MOSFET’) has higher impedance than a bipolar transistor. As a result, the MOSFET has a relatively large power gain and a relatively simple gate driving circuit. Also, the MOSFET is a unipolar device, so it has an advantage that there is essentially no time delay generated by means of an accumulation or a recombination of minority carriers while the device is turned-off. Therefore, there is a tendency that the application into a switching mode power supply, a lamp ballast and a motor driving circuit has been gradually spread.

As such a MOSFET, a lateral double diffused MOSFET (LDMOSFET) using a planar diffusion technique has been widely used.

The LDMOS transistor formed by the double diffusion process may have certain problems. For example, since a channel and a drain thereof are implemented in a lateral direction, the on-resistance may be relatively large due to the low channel density, and the size of the device may become relatively large as compared to the length of the drain.

### SUMMARY

Embodiments of the invention provide a semiconductor device and a fabricating method thereof.

The semiconductor device may comprise: a semiconductor substrate with a first conductive well area; a conductive body in the well-area; a first conductive source area in the body; a first conductive drift region and a drain area in a vertical region of the well area other than the body; and a gate electrode between the source area and the drain area.

Alternatively, the semiconductor device may comprise: a first conductive well area in a semiconductor substrate; a conductive body in the well area; a first conductive source area in the body; a first conductive drift region and a drain area in a region of the well area other than the body, higher than the source area; and a gate electrode between the source area and the drain area.

The method of fabricating a semiconductor device may comprise the steps of: forming a drift region by implanting a first conductive impurity ion into a first conductive well area in a semiconductor substrate; forming a vertical drift region by etching a portion of the drift region and the well area; forming a body by implanting a second conductive impurity ion into the etched well area; forming a vertical spacer on the side wall of the drift region; forming a gate oxide film, a gate electrode, and a gate sidewall spacer between the body and the vertical spacer; and forming a source area and a drain area by implanting a high concentration of first conductive impurity ions into the drift region and the body.

### BRIEF DESCRIPTION OF THE DRAWINGS

FIGS. 1 to 7 are views explaining a semiconductor device and a fabricating method thereof according to embodiments of the invention.

### DETAILED DESCRIPTION OF THE EMBODIMENTS

Hereinafter, a semiconductor device and a fabricating method thereof will be described with reference to the accompanying drawings.

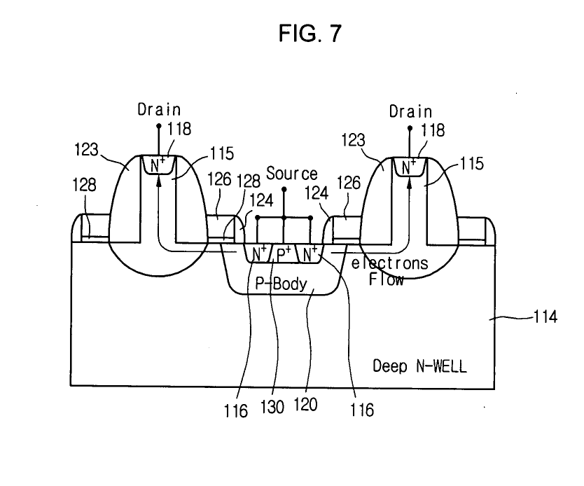

FIG. 7 is a view explaining a structure of a DMOS transistor according to embodiments of the invention.

The DMOS transistor of FIG. 7 may be formed in an N-well area 114 on the upper side of a silicon substrate. The DMOS transistor comprises an N type doped source area 116 and drain area 118, wherein the N type doped source area 116 is formed within a P type doped well. The well area is referred to herein as a P type body 120. Also, a high-concentration doped body area 130 is formed in the P type body 120. The body area 130 is included so that it favorably contacts the P type body 120. The body area 130 is doped in a higher concentration than the P type body 120. Impurities or dopants in the N type doped regions or structures may include boron (B), and impurities or dopants in the P type doped regions or structures may include phosphorous (P), arsenic (As) and/or antimony (Sb).

The drain area 118 is formed on both sides of the P type body 120, and is positioned above the source area 116. In other words, the drain area 118 is formed in a vertical direction or vertical region of N-drift region 115, and at least a portion of the path of the electrons or other carriers flowing from the source area 116 to the drain area 118 is in a vertical direction. As shown in FIG. 7, the lowermost boundary of drain 118 is above the uppermost surface of source 116, P+ body 130, and/or P type body 120.

At least a portion of an N-drift region 115 where the electrons or other carriers flow from the source area 116 to the drain area 118 is a vertical structure (e.g., has a portion where the cross-section taken along the plane shown in FIG. 7 has a vertical axis that is longer than the corresponding horizontal axis), so that the current flows in a vertical direction. A spacer 123 is on the vertical sides of the N-drift region 115 (and, in one embodiment, the drain area 118). In one example, spacer 123 comprises an oxide (e.g., silicon dioxide). In another example, spacer 123 comprises an oxide-nitride bilayer (e.g., silicon nitride on silicon dioxide). Also, a gate electrode 126 is between the drain area 118 and the source area 116. Alternatively, a gate electrode 126 may be between each of the source areas 116 and the nearest vertical drain 118.

The gate electrode 126 generally comprises polysilicon doped with an impurity (in one embodiment, the same type of impurity as the source 116 and drain 118), and is isolated from the N-well area 114 by a gate oxide film 128. The gate oxide film 128 may include oxide, nitride, or the combination thereof (that is, a stacked silicon nitride-on-silicon dioxide [NO] or silicon dioxide-on-silicon nitride-on-silicon dioxide [ONO] layer). A spacer 124 may be formed on the side wall of the gate electrode 126. The spacer 124 may include an oxide such as silicon oxide and/or a nitride such as silicon nitride.

The present DMOS transistor can reduce the size of the device by positioning N-drift region 115 and the drain area 118 formed in a vertical structure (e.g., positioning drain 118 in a region of a structure completely above the uppermost surface of source 116, body 120 and/or gate 126). In other words, the drain area is not positioned in a horizontal direction relative to the source area, but the (N—) drift region 115 and the drain 118 are positioned in a vertical direction above source 116, body 120 and/or gate 126, making it possible to reduce the size of the device.

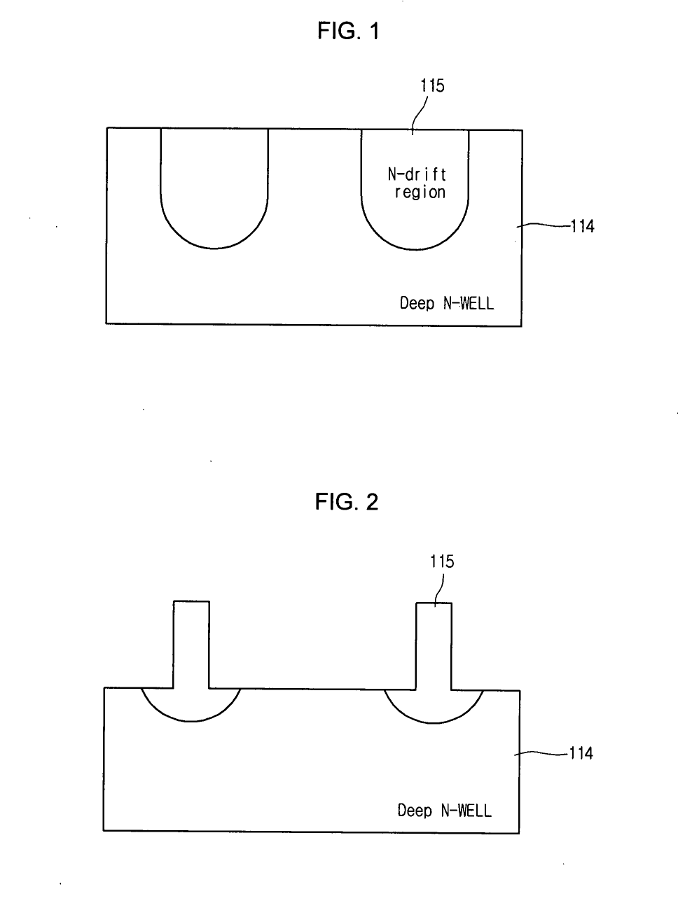

FIGS. 1 to 7 are views explaining an exemplary method of fabricating a DMOS transistor according to embodiments of the invention.

Referring to FIG. 1, a photoresist pattern is formed on a silicon substrate provided with an N-well area 114 to form an N-drift region 115 by implanting an N type impurity ion thereto. The substrate may be a single crystal silicon substrate into which N type impurities have been implanted in a low dose or concentration to form deep N-well 114, or an epitaxial layer of silicon having a low dose or concentration of N type impurities incorporated therein (e.g., by co-deposition). Then, the photoresist pattern is removed.

Referring to FIG. 2, a second photoresist pattern is formed on the upper side of the N-well area 114 and the N-drift region 115, and a portion of the N-drift region 115 and an upper portion of the N-well area 114 are removed by a dry etching process (for example, a reactive ion etching (RIE) process). In other words, the etched portions of the N-drift region 115 and the N-well area 114 are etched to a predetermined depth, similarly to a trench forming process. As a result, the non-etched N-drift region 115 is generally higher than the remaining N-well area 114, and the N-drift region 115 has a vertical structure.

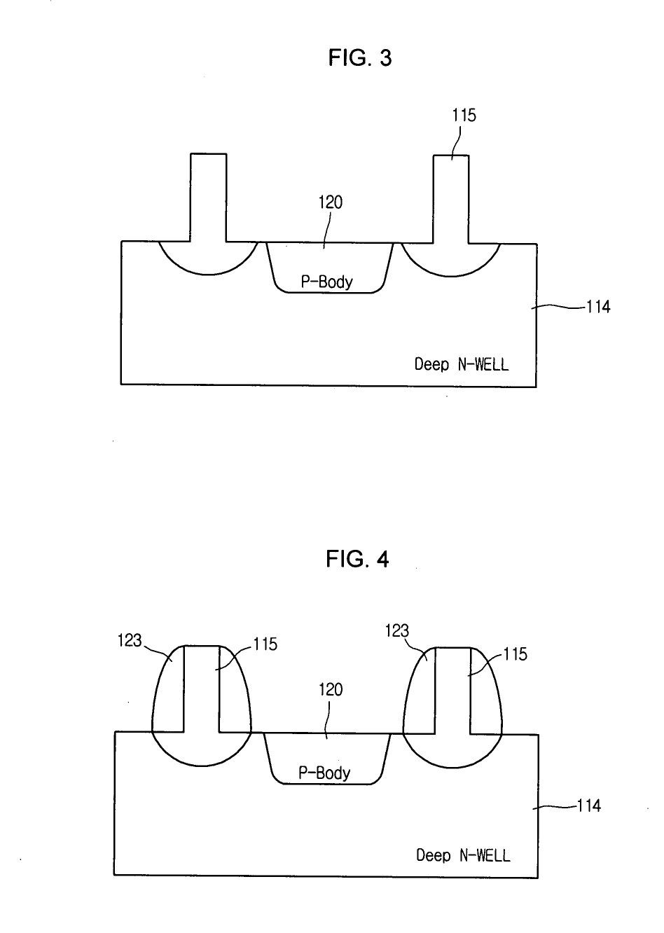

Referring to FIG. 3, a third (predetermined) photoresist pattern is formed between (and preferably over) the vertical N-drift regions 115 and then, a P type impurity ion is implanted into the exposed substrate (e.g., deep N-well 114) to form a P type body 120. Then, as shown in FIG. 4, an oxide spacer 123 is formed on the vertical wide wall of the N-drift region 115. The oxide spacer 123 insulates a subsequently formed gate electrode 126.

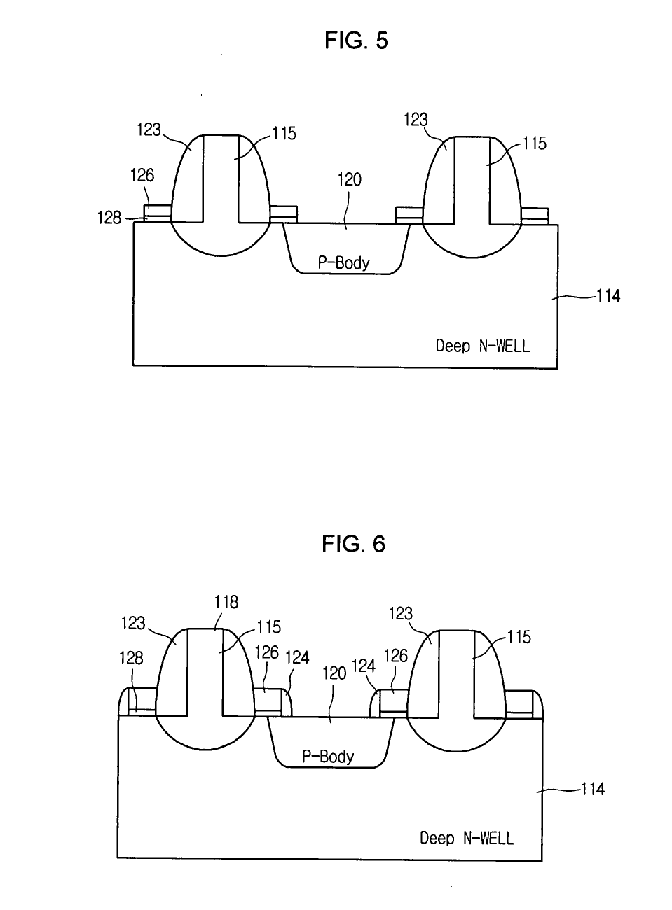

Referring to FIG. 5, a gate oxide film 128 and a gate electrode 126 are formed over the region of the substrate between the P type body 120 (where a source area is subsequently formed) and the N-drift region 115 (where a drain area is subsequently formed). Generally, the gate oxide film 128 can be formed by wet or dry thermal oxidation, or by deposition (e.g., chemical vapor deposition [CVD], which may be plasma-assisted) of silicon dioxide from a conventional silicon dioxide source (e.g., silane or TEOS). The gate electrode 126 can be formed by depositing a doped polysilicon layer doped with an impurity on the gate oxide film 128 by chemical vapor deposition, or a non-doped polysilicon layer deposited by chemical vapor deposition can be subsequently doped by ion implantation. Such a polysilicon layer and an oxide film are sequentially patterned by photolithography to form the gate electrode 126 and the gate oxide film 128.

Referring to FIG. 6, an oxide and/or nitride layer may be deposited to a predetermined thickness by chemical vapor deposition on the substrate (e.g., P well 114, vertical drift region 115, and vertical spacer 123), including the gate electrode 126, and is then etched to form a spacer 124 on the side wall of the gate electrode 126. The spacer 124 may comprise an oxide such as silicon oxide and/or a nitride such as silicon nitride.

Then, referring to FIG. 7, the source area 116 and the drain area 118 are formed by implanting a high-concentration N type impurity ion into the N-drift region 115 and the P type body 120 using a patterned photoresist (not shown) as a mask, and then implanting a high-concentration P type impurity ion into the P type body 120 using a different patterned photoresist (not shown) as a mask to form P+ body 130. In each case, the mask is located over regions of the substrate 114, gate 126 and/or vertical drift region 115 in which the dopant is not desired to be implanted. It is not necessary for the patterned photoresist to completely cover the spacers 123 and 126, since implantation of impurities into the spacers (or other insulator material) does not affect the electrical function of the insulating material, and they can function as a mask. Herein, as the high-concentration N type impurity ion, arsenic (As) or phosphorous (P) can be used, and as the high-concentration P type impurity ion, boron (B) can be used.

Thereafter, processes for forming contacts and/or wiring are additionally made. In one embodiment, the same voltage or potential is applied to each gate 126, and substantially the same power (e.g., voltage or electropotential increase or decrease as a function of time) is applied across each source 116 and drain 118.

The DMOS transistor according to the above method forms an N-drift region 115 and the drain area 118 in a vertical structure, making it possible to minimize or reduce the size of the device relative to an otherwise identical device in which the draft region and drain are co-planar (e.g., horizontal) with the source and (when present) body region(s). The present DMOS transistor has advantages in that the size of the device is relatively small, and the on-resistance may be relatively low because of a relative increase in the channel density.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a semiconductor substrate having a first conductive well area;
a conductive body in the first conductive well area;
a first conductive source area in the conductive body;
a first conductive drift region and a drain area in a vertical region of the well area other than the body; and
a gate electrode between the source area and the drain area.

2. The semiconductor device according to claim 1, wherein the drift region comprises a concentration of impurity ions higher than that of the well area.

3. The semiconductor device according to claim 1, wherein the drain area comprises a concentration of impurity ions higher than that of the drift region.

4. The semiconductor device according to claim 1, further comprising spacers on side walls of the drift region and the drain area.

5. The semiconductor device according to claim 4, wherein the spacers comprise an oxide.

6. The semiconductor device according to claim 1, further comprising a sidewall spacer on opposed sides of the gate electrode.

7. A semiconductor device comprising:
a semiconductor substrate having a first conductive well area;
a conductive body in the first conductive well area;
a first conductive source area in the conductive body;
a first conductive drift region and a drain area in the first conductive well area other than the body, higher than the source area; and
a gate electrode between the first conductive source area and the drain area.

8. The semiconductor device according to claim 7, wherein electrons flow in a vertical direction from at least part of the source area to the drain area.

9. The semiconductor device according to claim 7, wherein the drain area is higher than the gate electrode.

10. The semiconductor device according to claim 7, further comprising a spacer on side walls of the drift region.

11. The semiconductor device according to claim 10, wherein the spacer comprises an oxide.

12. The semiconductor device according to claim 11, wherein the drift region and the gate electrode are insulated by the oxide spacer.

13. A method of fabricating a semiconductor device, comprising the steps of:
forming a drift region by implanting a first conductive impurity ion into a first conductive well area in a semiconductor substrate;
forming a vertical drift region by etching a portion of the drift region and the first conductive well area;
forming a body by implanting a second conductive impurity ion into the etched first conductive well area;
forming a vertical spacer on side walls of the vertical drift region;
forming a gate oxide film, a gate electrode, and a gate sidewall spacer between the body and the vertical spacer; and
forming source and drain areas by implanting a first conductive high-concentration impurity ion into the vertical drift region and the body.

14. The method according to claim 13, wherein the drain area is higher than the source area.

15. The method according to claim 13, wherein the vertical spacer comprises an oxide.
